(19) United States
(12) Patent Application Publication
(10) Pub. No.: US 2024/0128355 A1
(43) Pub. Date: Apr. 18, 2024

(54) SACRIFICIAL SOURCE/DRAIN FOR METALLIC SOURCE/DRAIN HORIZONTAL GATE ALL AROUND ARCHITECTURE

(71) Applicant: Applied Materials, Inc., Santa Clara, CA (US)

(72) Inventors: Nicolas Breil, Alviso, CA (US); Byeong Chan Lee, San Jose, CA (US)

(73) Assignee: Applied Materials, Inc., Santa Clara, CA (US)

(21) Appl. No.: 18/378,850

(22) Filed: Oct. 11, 2023

Related U.S. Application Data
(60) Provisional application No. 63/417,009, filed on Oct. 18, 2022.

(51) Int. Cl. H01L 29/66; H01L 21/8234; H01L 27/088; H01L 29/06; H01L 29/08; H01L 29/423; H01L 29/775; H01L 29/786

(52) U.S. Cl. CPC H01L 29/66545; H01L 21/823412; H01L 21/823418; H01L 27/088; H01L 29/0673; H01L 29/0847; H01L 29/42392; H01L 29/66439; H01L 29/775; H01L 29/78696

(57) ABSTRACT

Semiconductor devices and methods of manufacturing the same are described. The method includes forming a source region and a drain region adjacent to a superlattice structure on a substrate. The source region and the drain region comprise a metallic silicide material. In some embodiments, a sacrificial material is first deposited and then removed to form a metallic silicide material in the source and drain region.

### CROSS-REFERENCE TO RELATED APPLICATIONS

This application claims priority to U.S. Provisional Application No. 63/417,009, filed Oct. 18, 2022, the entire disclosure of which is hereby incorporated by reference herein.

### TECHNICAL FIELD

Embodiments of the disclosure generally relate to semiconductor devices. More particularly, embodiments of the disclosure are directed to gate all around (GAA) devices having a metallic source drain region.

### BACKGROUND

The transistor is a key component of most integrated circuits. Since the drive current, and therefore speed, of a transistor is proportional to the gate width of the transistor, faster transistors generally require larger gate width. Thus, there is a trade-off between transistor size and speed, and “fin” field-effect transistors (finFETs) have been developed to address the conflicting goals of a transistor having maximum drive current and minimum size. FinFETs are characterized by a fin-shaped channel region that greatly increases the size of the transistor without significantly increasing the footprint of the transistor and are now being applied in many integrated circuits. However, finFETs have their own drawbacks.

As the feature sizes of transistor devices continue to shrink to achieve greater circuit density and higher performance, there is a need to improve transistor device structure to improve electrostatic coupling and reduce negative effects such as parasitic capacitance and off-state leakage. Examples of transistor device structures include a planar structure, a fin field effect transistor (FinFET) structure, and a horizontal gate all around (hGAA) structure. The hGAA device structure includes several lattice matched channels suspended in a stacked configuration and connected by source/drain regions. The hGAA structure provides good electrostatic control and can find broad adoption in complementary metal oxide semiconductor (CMOS) wafer manufacturing.

In GAA architectures, it is a known challenge that the current going through the bottom sheet is lower than the top sheet due to the higher series resistance. Indeed, the electrical carriers have to travel through the height of the S/D epitaxial material before being injected into the bottom sheet. As a solution, engineers have focused on increasing the doping level in epitaxial S/D in order to minimize the S/D resistance. Changing the doping level, however, is problematic as devices become smaller. Accordingly, there is a need for improved devices and methods for forming gate-all-around devices.

### SUMMARY

One or more embodiments of the disclosure are directed to methods of forming a semiconductor device. In one or more embodiments, a method of forming a semiconductor device comprises: forming a source trench and a drain trench adjacent to a superlattice structure on a substrate, the superlattice structure comprising a plurality of horizontal channel layers and a corresponding plurality of semiconductor material layers alternatingly arranged in a plurality of stacked pairs; depositing a sacrificial material in the source trench and in the drain trench; forming a replacement metal gate structure on a top surface of the superlattice structure; opening a contact trench adjacent the replacement metal gate structure, the contact trench extending to a top surface of the sacrificial material; selectively removing the sacrificial material through the contact trench; forming a source region and a drain region adjacent the replacement metal gate structure; and filling the contact trench, the source trench, and the drain trench with a metal fill layer.

Additional embodiments of the disclosure are directed to methods of forming a semiconductor device. In one or more embodiments, a method of forming a semiconductor device comprises: forming a source region and a drain region adjacent a superlattice structure on a substrate, the superlattice structure comprising a plurality of horizontal channel layers and a corresponding plurality of semiconductor material layers alternatingly arranged in a plurality of stacked pairs, wherein the source region and the drain region comprise a metallic silicide material.

Further embodiments of the disclosure are directed to a non-transitory computer readable medium. In one or more embodiments, a non-transitory computer readable medium includes instructions, that, when executed by a controller of a processing chamber, causes the processing chamber to perform the operations of: form a source region and a drain region adjacent a superlattice structure on a substrate, the superlattice structure comprising a plurality of horizontal channel layers and a corresponding plurality of semiconductor material layers alternatingly arranged in a plurality of stacked pairs, wherein the source region and the drain region comprise a metallic silicide material.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a process flow diagram of a method for forming a semiconductor device in accordance with some embodiments of the present disclosure;

FIG. 2A illustrates a cross-section view of a device according to one or more embodiments;

FIG. 2B illustrates a cross-section view of a device according to one or more embodiments;

FIG. 2C illustrates a cross-section view of a device according to one or more embodiments;

FIG. 2D illustrates a cross-section view of a device according to one or more embodiments;

FIG. 2E illustrates a cross-section view of a device according to one or more embodiments;

FIG. 2F illustrates a cross-section view of a device according to one or more embodiments;

FIG. 2G illustrates a cross-section view of a device according to one or more embodiments;

FIG. 2H illustrates a cross-section view of a device according to one or more embodiments;

FIG. 3 illustrates a process flow diagram of a method for forming a semiconductor device in accordance with some embodiments of the present disclosure;

FIG. 4A illustrates a cross-section view of a device according to one or more embodiments;

FIG. 4B illustrates a cross-section view of a device according to one or more embodiments;

FIG. 4C illustrates a cross-section view of a device according to one or more embodiments;

FIG. 4D illustrates a cross-section view of a device according to one or more embodiments;

FIG. 4E illustrates a cross-section view of a device according to one or more embodiments;

FIG. 4F illustrates a cross-section view of a device according to one or more embodiments;

FIG. 4G illustrates a cross-section view of a device according to one or more embodiments;

FIG. 4H illustrates a cross-section view of a device according to one or more embodiments and

FIG. 5 illustrates a cluster tool according to one or more embodiments.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

As used in this specification and the appended claims, the terms “precursor,” “reactant,” “reactive gas” and the like are used interchangeably to refer to any gaseous species that can react with the substrate surface.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

As used herein, the term “field effect transistor” or “FET” refers to a transistor that uses an electric field to control the electrical behavior of the device. Enhancement mode field effect transistors generally display very high input impedance at low temperatures. The conductivity between the drain and source terminals is controlled by an electric field in the device, which is generated by a voltage difference between the body and the gate of the device. The FET's three terminals are source (S), through which the carriers enter the channel; drain (D), through which the carriers leave the channel; and gate (G), the terminal that modulates the channel conductivity. Conventionally, current entering the channel at the source (S) is designated Is and current entering the channel at the drain (D) is designated ID. Drain-to-source voltage is designated VDS. By applying voltage to gate (G), the current entering the channel at the drain (i.e., ID) can be controlled.

The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p region. If the MOSFET is a p-channel or pMOS FET, then the source and drain are p+ regions and the body is an n region. The source is so named because it is the source of the charge carriers (electrons for n-channel, holes for p-channel) that flow through the channel; similarly, the drain is where the charge carriers leave the channel.

As used herein, the term “fin field-effect transistor (FinFET)” refers to a MOSFET transistor built on a substrate where the gate is placed on two or three sides of the channel, forming a double- or triple-gate structure. FinFET devices have been given the generic name FinFETs because the channel region forms a “fin” on the substrate. FinFET devices have fast switching times and high current density.

As used herein, the term “gate all-around (GAA),” is used to refer to an electronic device, e.g., a transistor, in which the gate material surrounds the channel region on all sides. The channel region of a GAA transistor may include nanowires or nano-slabs, or nano-sheets, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

As used herein, the term “nanowire” refers to a nanostructure, with a diameter on the order of a nanometer (10⁻⁹ meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term “nanosheet” refers to a two-dimensional nanostructure with a thickness in a scale ranging from about 0.1 nm to about 1000 nm.

The embodiments of the disclosure are described by way of the Figures, which illustrate devices (e.g., transistors) and processes for forming transistors in accordance with one or more embodiments of the disclosure. The processes shown are merely illustrative possible uses for the disclosed processes, and the skilled artisan will recognize that the disclosed processes are not limited to the illustrated applications.

One or more embodiments of the disclosure are described with reference to the Figures. In the method of one or more embodiments, horizontal gate all-around transistors with a metallic source/drain are fabricated using a standard process flow. In one or more embodiments, a source region and a drain region are formed adjacent to a superlattice structure on a substrate, where the source region and the drain region comprise a metallic silicide material. After the source/drain cavity is formed, a sacrificial source/drain material is deposited in the source/drain cavity, the replacement metal gate (RMG) is formed, the contact trench is opened, the sacrificial source/drain material is selectively removed, contact epitaxial layer is selectively grown, and a conformal silicide layer is formed on the epitaxial layer.

As used herein, the term “conformal” means that the layer adapts to the contours of a feature or a layer. Conformality of a layer is typically quantified by a ratio of the average thickness of a layer deposited on the sidewalls of a feature to the average thickness of the same deposited layer on the field, or upper surface, of the substrate.

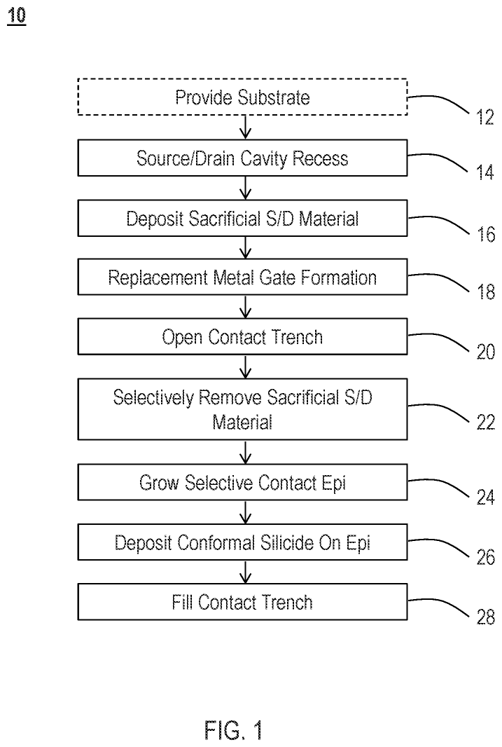

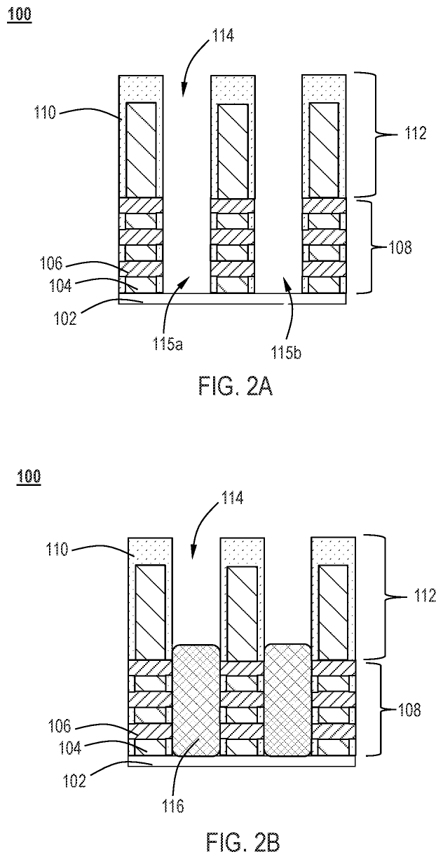

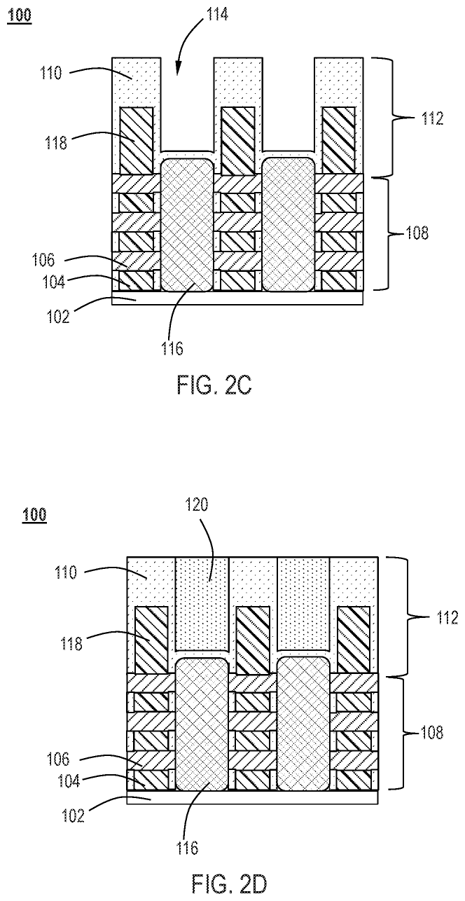

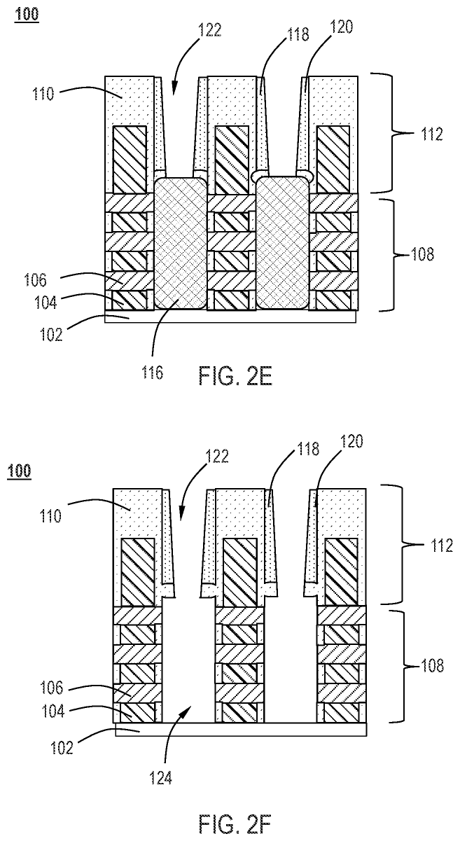

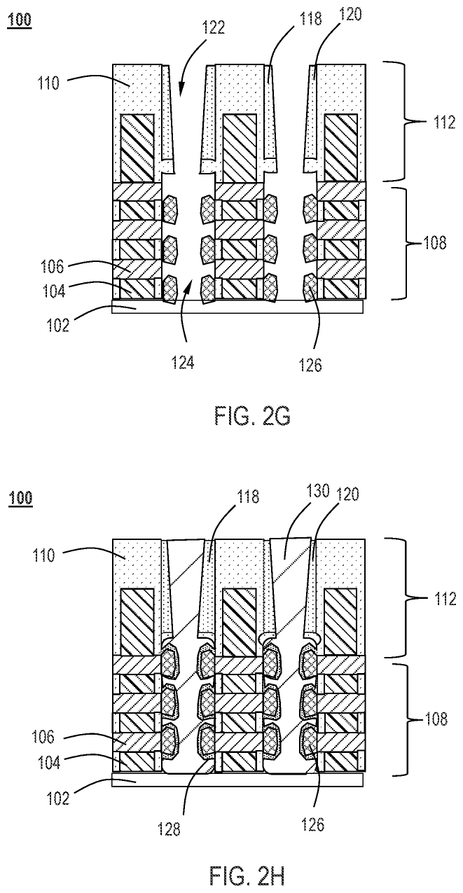

FIG. 1 illustrates a process flow diagram for a method 10 for forming a semiconductor device in accordance with some embodiments of the present disclosure. FIGS. 2A-2H depict the stages of fabrication of semiconductor structures in accordance with some embodiments of the present disclosure. In one or more embodiments, the sacrificial material is deposited and then replaced, followed by epitaxial growth of the source/drain region.

The method 10 is described below with respect to FIGS. 1-2F. FIGS. 2A-2H are cross-sectional views of an electronic device (e.g., a hGAA) according to one or more embodiments. The method 10 may be part of a multi-step fabrication process of a semiconductor device. Accordingly, the method 10 may be performed in any suitable process chamber coupled to a cluster tool. The cluster tool may include process chambers for fabricating a semiconductor device, such as chambers configured for etching, deposition, physical vapor deposition (PVD), chemical vapor deposition (CVD), oxidation, or any other suitable chamber used for the fabrication of a semiconductor device.

FIGS. 2A-2H are the fabrication steps of operations 12 through 28 in FIG. 1. Referring to FIG. 1, the method 10 of forming the device 100 begins at operation 12, by providing a substrate 102. In some embodiments, the substrate 102 may be a bulk semiconductor substrate. As used herein, the term “bulk semiconductor substrate” refers to a substrate in which the entirety of the substrate is comprised of a semiconductor material. The bulk semiconductor substrate may comprise any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In some embodiments, the semiconductor material is silicon (Si). In one or more embodiments, the semiconductor substrate 102 comprises a semiconductor material, e.g., silicon (Si), carbon (C), germanium (Ge), silicon germanium (SiGe), germanium tin (GeSn), other semiconductor materials, or any combination thereof. In one or more embodiments, the substrate 102 comprises one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In some embodiments, the semiconductor material may be a doped material, such as n-doped silicon (n-Si), or p-doped silicon (p-Si). In some embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers. In one or more embodiments, the dopant is selected from one or more of boron (B), gallium (Ga), phosphorus (P), arsenic (As), other semiconductor dopants, or combinations thereof.

In some embodiments, a replacement gate structure (e.g., a dummy gate structure 112) is formed atop a superlattice structure 108. The dummy gate structure 112 defines the channel region of the transistor device. The dummy gate structure 112 may be formed using any suitable conventional deposition and patterning process known in the art. In one or more embodiments, the dummy gate structure 112 comprises one or more of titanium nitride (TiN), tantalum nitride (TaN), tungsten (W), and titanium aluminum (TiAl).

In some embodiments, sidewall spacers 110 are formed along outer sidewalls of the dummy gate structure 112. The sidewall spacers 110 may comprise suitable insulating materials known in the art, for example, silicon nitride, silicon oxide, silicon oxynitride, silicon carbide, or the like. In some embodiments, the sidewall spacers are formed using any suitable conventional deposition and patterning process known in the art, such as atomic layer deposition, plasma enhanced atomic layer deposition, plasma enhanced chemical vapor deposition or low-pressure chemical vapor deposition.

At least one superlattice structure 108 is formed atop the top surface of the substrate 102. In one or more embodiments, the superlattice structure 108 comprises a plurality of semiconductor material layers 106 and a corresponding plurality of nanosheet channel layers 104 alternatingly arranged in a plurality of stacked pairs. In some embodiments the plurality of stacked groups of layers comprises a silicon (Si) and silicon germanium (SiGe) group. In some embodiments, the plurality of semiconductor material layers 106 comprise silicon germanium (SiGe), and the plurality of nanosheet channel layers 104 comprise silicon (Si). In other embodiments, the plurality of nanosheet channel layers 104 comprising silicon germanium (SiGe), and the plurality of semiconductor materials layers comprise silicon (Si).

In some embodiments, the plurality of semiconductor material layers 106 and corresponding plurality of nanosheet channel layers 104 can comprise any number of lattice matched material pairs suitable for forming a superlattice structure 108. In some embodiments, the plurality of semiconductor material layers 106 and corresponding plurality of nanosheet channel layers 104 comprise from about 2 to about 50 pairs of lattice matched materials.

In one or more embodiments, the thickness, ti, of the plurality of semiconductor material layers 106 and the plurality of nanosheet channel layers 104 are in the range of from about 2 nm to about 50 nm, in the range of from about 3 nm to about 20 nm, or in a range of from about 2 nm to about 15 nm.

A channel region 114 separates the superlattice structure 108 from an adjacent superlattice structure 108. At operation 14, the channel region 114 is recessed to form a source trench 115a and a drain trench 115b. In one or more embodiments, a source trench 155a and a drain trench 115b are formed adjacent (i.e., on either side) the superlattice structure 108.

Referring to FIG. 2B and to FIG. 1, at operation 16, a sacrificial material 116 is deposited in the channel region 114 and onto the bottom surface of the source/drain trenches 115a/115b. The sacrificial material 116 may comprise any suitable material known to the skilled artisan. In some embodiments, the sacrificial material 116 is amorphous. In one or more embodiments, the sacrificial material 116 comprises one or more of silicon (Si), germanium (Ge), silicon germanium (SiGe), silicon carbide (SiC), aluminum oxide (AlOx), silicon oxide (SiOx), silicon oxycarbide (SiOC), and the like. In some embodiments, the sacrificial material 116 is a stressed material that is later replaced. The sacrificial stressed materials may be characterized by an amount of stress greater than the stress in the surround layers.

The sacrificial material 116 can be deposited using any suitable conventional deposition process known in the art, such as atomic layer deposition, plasma enhanced atomic layer deposition, plasma enhanced chemical vapor deposition, or low-pressure chemical vapor deposition.

In one or more embodiments, the thickness of the sacrificial material 116 is in the range of from about 2 nm to about 50 nm, in the range of from about 3 nm to about 20 nm, or in a range of from about 2 nm to about 15 nm.

Referring to FIG. 2B, in some embodiments, the sacrificial material 116 may be deposited in the channel region 114 and onto the bottom surface of the source/drain trenches 115a, 115b and on the sidewalls of the superlattice structure 108.

Referring to FIG. 1, at operation 18, the formation of the semiconductor device, e.g., GAA, continues according to traditional procedures with nanosheet release and replacement metal gate formation. Specifically, as illustrated in FIG. 2C, the plurality of semiconductor material layers 106 are selectively etched between the plurality of horizontal channel layers 104 in the superlattice structure 108. For example, where the superlattice structure 108 is composed of silicon (Si) layers and silicon germanium (SiGe) layers, the silicon germanium (SiGe) is selectively etched to form channel nanowires. The plurality of semiconductor material layers 106, for example silicon germanium (SiGe), may be removed using any well-known etchant that is selective to the plurality of horizontal channel layers 104 where the etchant etches the plurality of semiconductor material layers 106 at a significantly higher rate than the plurality of horizontal channel layers 104. In some embodiments, a selective dry etch or wet etch process may be used. In some embodiments, where the plurality of horizontal channel layers 104 are silicon (Si) and the plurality of semiconductor material layers 106 are silicon germanium (SiGe), the layers of silicon germanium may be selectively removed using a wet etchant such as, but not limited to aqueous carboxylic acid/nitric acid/HF solution and aqueous citric acid/nitric acid/HF solution. The removal of the plurality of semiconductor material layers 106 leaves voids between the plurality of horizontal channel layers 104. The voids between the plurality of horizontal channel layers 104 have a thickness of about 3 nm to about 20 nm. The remaining horizontal channel layers 104 form a vertical array of channel nanowires that are coupled to the source/drain regions. The channel nanowires run parallel to the top surface of the substrate 102 and are aligned with each other to form a single column of channel nanowires.

In one or more embodiments, a high-k dielectric is formed. The high-k dielectric can be any suitable high-k dielectric material deposited by any suitable deposition technique known to the skilled artisan. The high-k dielectric of some embodiments comprises hafnium oxide. In some embodiments, a conductive material such as titanium nitride (TiN), tungsten (W), cobalt (Co), aluminum (Al), or the like is deposited on the high-k dielectric to form the replacement metal gate 118. The conductive material may be formed using any suitable deposition process such as, but not limited to, atomic layer deposition (ALD) in order to ensure the formation.

Referring to FIG. 2D, a contact material 120 is deposited over the sacrificial material 116.

With reference to FIG. 1 and FIG. 2E, at operation 20 a contact trench 122 is opened. In one or more embodiments, the contact trench extends to the sacrificial material 116. The contact trench 122 may be formed by any suitable means known to the skilled artisan. In some embodiments, the contact trench 122 is formed by etching.

Referring to FIG. 1 and FIG. 2F, at operation 22, the sacrificial material 116 is selectively removed to form a source/drain trench 124. The sacrificial material 116 may be selectively removed by any suitable means known to the skill artisan. In one or more embodiments, the sacrificial material 116 is selectively removed.

At operation 24, as illustrated in FIG. 2G, a source/drain material 126 is selectively grown in the source/drain trench 124 adjacent to the semiconductor material layers 106. In one or more embodiments, the source/drain material 126 is epitaxially grown. The source/drain material 126 may comprise any suitable material known to the skilled artisan. In one or more embodiments, the source/drain material 126 comprises silicon germanium (SiGe), silicon germanium doped with boron (SiGeB), silicon phosphorus (SiP), silicon phosphorus doped with carbon (SiPC), germanium (Ge), germanium doped with boron (GeB).

Referring to FIG. 1 and FIG. 2H, at operation 26, a silicide layer 128 is formed on the source/drain material 126. In one or more embodiments, the silicide layer 128 may be a substantially conformal layer of silicide. As used herein, a layer which is “substantially conformal” refers to a layer where the thickness is about the same throughout. A layer which is substantially conformal varies in thickness by less than or equal to about 10%, 5%, 2% or 0.5%.

Contact metallization is then completed at operation 28 by depositing a metal fill 130 in the contact trench 122 and in the source/drain trench 124.

The metal fill 130 may comprise any suitable material known to the skilled artisan. In one or more embodiments, the metal fill 130 comprises one or more of cobalt (Co), molybdenum (Mo), ruthenium (Ru), and tungsten (W).

In some embodiments, the silicide layer 128 in combination with the metal fill 130 forms a metal silicide in the source trench and in the drain trench. Accordingly, in one or more embodiments, the source/drain trench 124 is filled with a metal silicide material comprising one or more of cobalt silicide (CoSi), molybdenum silicide (MoSi), ruthenium (RuSi), and tungsten silicide (WSi).

In some embodiments, the method 10 of FIG. 1 is integrated such that there is no vacuum break. In one or more embodiments, the deposition of the sacrificial material (operation 16), the replacement gate formation (operation 18), the opening of the contact trench (operation 20), the selective removal of the sacrificial material (operation 22), the source/drain growth (operations 24 and 26), and the filling of the contact trench (operation 28) can be integrated such that there is no vacuum break between the operations.

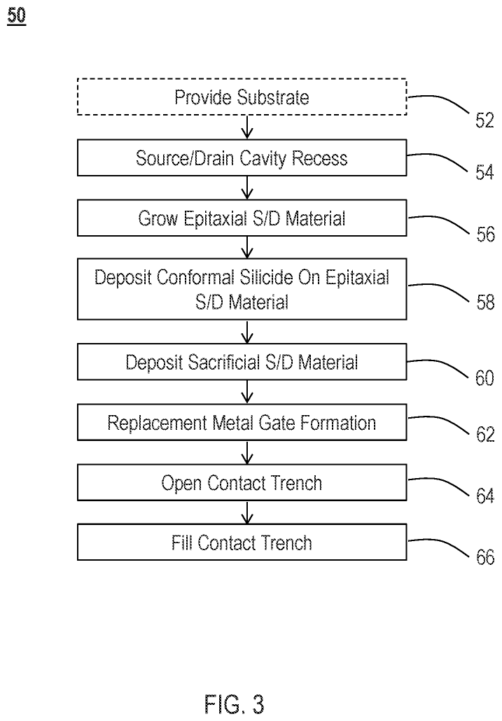

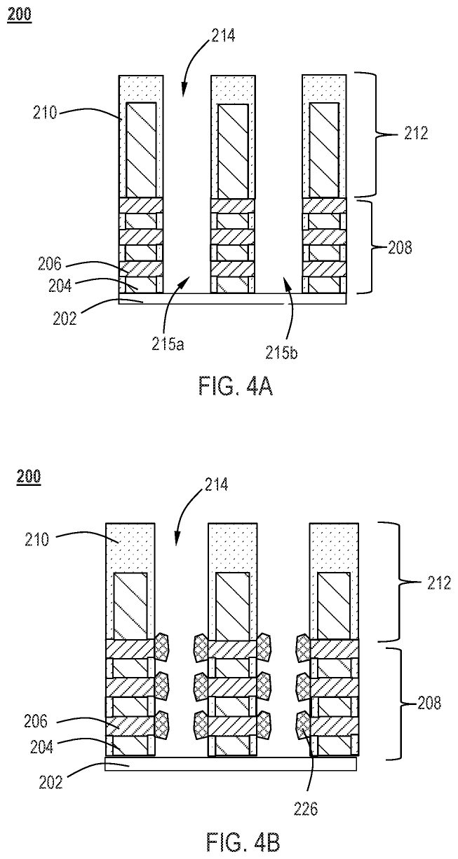

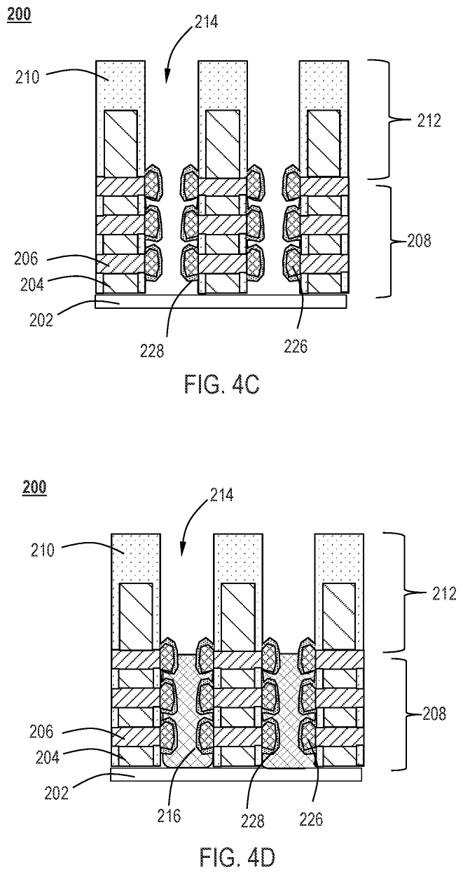

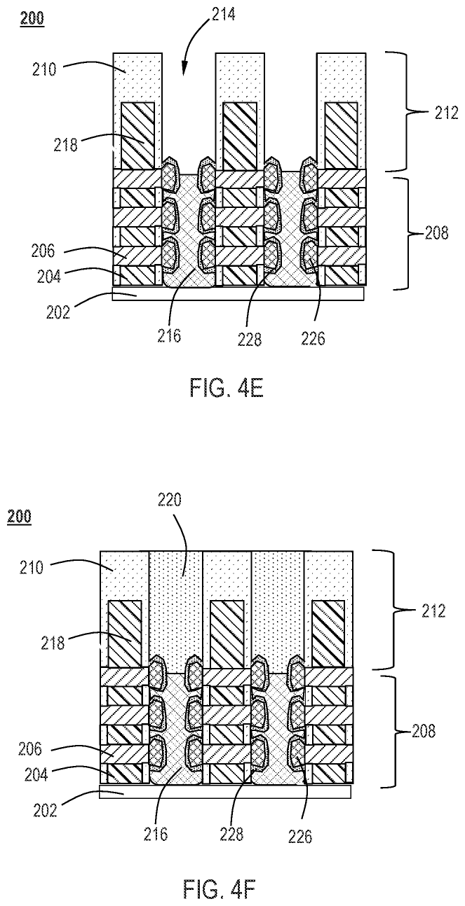

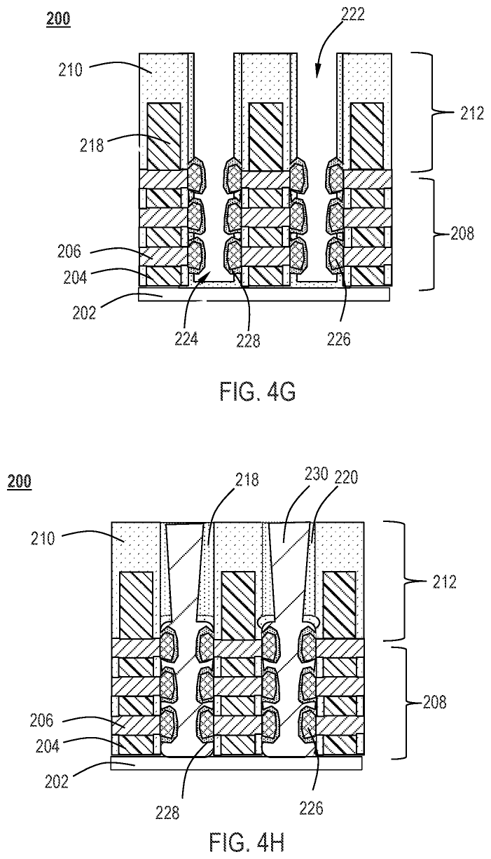

FIG. 3 illustrates a process flow diagram for a method 50 for forming a semiconductor device in accordance with some embodiments of the present disclosure. FIGS. 4A-4H depict the stages of fabrication of semiconductor structures in accordance with some embodiments of the present disclosure. In one or more embodiments, the source/drain region is epitaxially grown, and then a replacement occurs to form a metal silicide. In one or more embodiments, a source region and a drain region are formed adjacent to a superlattice structure on a substrate. The source region and the drain region comprise a metallic silicide material.

The method 50 is described below with respect to FIGS. 3-4H. FIGS. 4A-4H are cross-sectional views of an electronic device (e.g., a hGAA) according to one or more embodiments. The method 50 may be part of a multi-step fabrication process of a semiconductor device. Accordingly, the method 50 may be performed in any suitable process chamber coupled to a cluster tool. The cluster tool may include process chambers for fabricating a semiconductor device, such as chambers configured for etching, deposition, physical vapor deposition (PVD), chemical vapor deposition (CVD), oxidation, or any other suitable chamber used for the fabrication of a semiconductor device.

FIGS. 4A-4H are the fabrication steps of operations 52 through 64 in FIG. 3. Referring to FIG. 3, the method 50 of forming the device 200 begins at operation 52, by providing a substrate 202. In some embodiments, the substrate 202 may be a bulk semiconductor substrate. As used herein, the term “bulk semiconductor substrate” refers to a substrate in which the entirety of the substrate is comprised of a semiconductor material. The bulk semiconductor substrate may comprise any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In some embodiments, the semiconductor material is silicon (Si). In one or more embodiments, the semiconductor substrate 202 comprises a semiconductor material, e.g., silicon (Si), carbon (C), germanium (Ge), silicon germanium (SiGe), germanium tin (GeSn), other semiconductor materials, or any combination thereof. In one or more embodiments, the substrate 202 comprises one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In some embodiments, the semiconductor material may be a doped material, such as n-doped silicon (n-Si), or p-doped silicon (p-Si). In some embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers. In one or more embodiments, the dopant is selected from one or more of boron (B), gallium (Ga), phosphorus (P), arsenic (As), other semiconductor dopants, or combinations thereof.

In some embodiments, a replacement gate structure (e.g., a dummy gate structure 212) is formed atop a superlattice structure 208. The dummy gate structure 212 defines the channel region of the transistor device. The dummy gate structure 212 may be formed using any suitable conventional deposition and patterning process known in the art. In one or more embodiments, the dummy gate structure 212 comprises one or more of titanium nitride (TiN), tantalum nitride (TaN), tungsten (W), and titanium aluminum (TiAl).

In some embodiments, sidewall spacers 210 are formed along outer sidewalls of the dummy gate structure 212. The sidewall spacers 210 may comprise suitable insulating materials known in the art, for example, silicon nitride, silicon oxide, silicon oxynitride, silicon carbide, or the like. In some embodiments, the sidewall spacers are formed using any suitable conventional deposition and patterning process known in the art, such as atomic layer deposition, plasma enhanced atomic layer deposition, plasma enhanced chemical vapor deposition or low-pressure chemical vapor deposition.

At least one superlattice structure 208 is formed atop the top surface of the substrate 202. In one or more embodiments, the superlattice structure 208 comprises a plurality of semiconductor material layers 206 and a corresponding plurality of nanosheet channel layers 204 alternatingly arranged in a plurality of stacked pairs. In some embodiments the plurality of stacked groups of layers comprises a silicon (Si) and silicon germanium (SiGe) group. In some embodiments, the plurality of semiconductor material layers 206 comprise silicon germanium (SiGe), and the plurality of nanosheet channel layers 204 comprise silicon (Si). In other embodiments, the plurality of nanosheet channel layers 204 comprising silicon germanium (SiGe), and the plurality of semiconductor materials layers comprise silicon (Si).

In some embodiments, the plurality of semiconductor material layers 206 and corresponding plurality of nanosheet channel layers 204 can comprise any number of lattice matched material pairs suitable for forming a superlattice structure 208. In some embodiments, the plurality of semiconductor material layers 206 and corresponding plurality of nanosheet channel layers 104 comprise from about 2 to about 50 pairs of lattice matched materials.

In one or more embodiments, the thickness, ti, of the plurality of semiconductor material layers 206 and the plurality of nanosheet channel layers 204 are in the range of from about 2 nm to about 50 nm, in the range of from about 3 nm to about 20 nm, or in a range of from about 2 nm to about 15 nm.

A channel region 214 separates the superlattice structure 208 from an adjacent superlattice structure 208. At operation 54, the channel region 214 is recessed to form a source trench 215a and a drain trench 215b. In one or more embodiments, a source trench 215a and a drain trench 215b are formed adjacent (i.e., on either side) the superlattice structure 208.

Referring to FIG. 4B and to FIG. 3, at operation 56, a source/drain material 226 is selectively grown in the source/drain trench 215a/215b adjacent to the semiconductor material layers 206. In one or more embodiments, the source/drain material 226 is epitaxially grown. The source/drain material 226 may comprise any suitable material known to the skilled artisan. In one or more embodiments, the source/drain material 126 comprises silicon germanium (SiGe), silicon germanium doped with boron (SiGeB), silicon phosphorus (SiP), silicon phosphorus doped with carbon (SiPC), germanium (Ge), germanium doped with boron (GeB).

Referring to FIG. 3 and FIG. 4C, at operation 58, a silicide layer 228 is formed on the source/drain material 226.

With reference to FIG. 3 and FIG. 4D, at operation 60, a sacrificial material 216 is deposited in the channel region 214 and onto the bottom surface of the source/drain trenches 215a/215b. The sacrificial material 216 may comprise any suitable material known to the skilled artisan. In some embodiments, the sacrificial material 216 is amorphous. In one or more embodiments, the sacrificial material 216 comprises one or more of silicon (Si), germanium (Ge), silicon germanium (SiGe), silicon carbide (SiC), aluminum oxide (AlOx), silicon oxide (SiOx), silicon oxycarbide (SiOC), and the like. In some embodiments, the sacrificial material 216 is a stressed material that is later replaced. The sacrificial stressed materials may be characterized by an amount of stress greater than the stress in the surrounding layers.

The sacrificial material 216 can be deposited using any suitable conventional deposition process known in the art, such as atomic layer deposition, plasma enhanced atomic layer deposition, plasma enhanced chemical vapor deposition, or low-pressure chemical vapor deposition.

In one or more embodiments, the thickness of the sacrificial material 216 is in the range of from about 2 nm to about 50 nm, in the range of from about 3 nm to about 20 nm, or in a range of from about 2 nm to about 15 nm.

Referring to FIG. 4D, in some embodiments, the sacrificial material 216 may be deposited in the channel region 214 and onto the bottom surface of the source/drain trenches 215a, 215b and on the sidewalls of the superlattice structure 108.

Referring to FIG. 3, at operation 62, the formation of the semiconductor device, e.g., GAA, continues according to traditional procedures with nanosheet release and replacement metal gate formation. Specifically, as illustrated in FIG. 4E, the plurality of semiconductor material layers 206 are selectively etched between the plurality of horizontal channel layers 204 in the superlattice structure 208. For example, where the superlattice structure 208 is composed of silicon (Si) layers and silicon germanium (SiGe) layers, the silicon germanium (SiGe) is selectively etched to form channel nanowires. The plurality of semiconductor material layers 206, for example silicon germanium (SiGe), may be removed using any well-known etchant that is selective to the plurality of horizontal channel layers 204 where the etchant etches the plurality of semiconductor material layers 206 at a significantly higher rate than the plurality of horizontal channel layers 204. In some embodiments, a selective dry etch or wet etch process may be used. In some embodiments, where the plurality of horizontal channel layers 204 are silicon (Si) and the plurality of semiconductor material layers 206 are silicon germanium (SiGe), the layers of silicon germanium may be selectively removed using a wet etchant such as, but not limited to aqueous carboxylic acid/nitric acid/HF solution and aqueous citric acid/nitric acid/HF solution. The removal of the plurality of semiconductor material layers 206 leaves voids between the plurality of horizontal channel layers 204. The voids between the plurality of horizontal channel layers 204 have a thickness of about 3 nm to about 20 nm. The remaining horizontal channel layers 204 form a vertical array of channel nanowires that are coupled to the source/drain regions. The channel nanowires run parallel to the top surface of the substrate 202 and are aligned with each other to form a single column of channel nanowires.

In one or more embodiments, a high-k dielectric is formed. The high-k dielectric can be any suitable high-k dielectric material deposited by any suitable deposition technique known to the skilled artisan. The high-k dielectric of some embodiments comprises hafnium oxide. In some embodiments, a conductive material such as titanium nitride (TiN), tungsten (W), cobalt (Co), aluminum (Al), or the like is deposited on the high-k dielectric to form the replacement metal gate 218. The conductive material may be formed using any suitable deposition process such as, but not limited to, atomic layer deposition (ALD) in order to ensure the formation.

Referring to FIG. 4F, a contact material 220 is deposited over the sacrificial material 216 in the source/drain regions and in the channel region 214.

With reference to FIG. 3 and FIG. 4G, at operation 64 a contact trench 222 is opened. In one or more embodiments, the contact trench extends to the source/drain region and the source/drain material 226 and the silicide layer 228. The contact trench 222 may be formed by any suitable means known to the skilled artisan. In some embodiments, the contact trench 222 is formed by etching. In one or more embodiments, the sacrificial material 216 is selectively removed to form a source/drain trench 224. The sacrificial material 216 may be selectively removed by any suitable means known to the skill artisan.

Referring to FIG. 4H and FIG. 3, at operation 66, contact metallization is then completed by depositing a metal fill 230 in the contact trench 222 and in the source/drain trench 224.

The metal fill 230 may comprise any suitable material known to the skilled artisan. In one or more embodiments, the metal fill 230 comprises one or more of cobalt (Co), molybdenum (Mo), ruthenium (Ru), and tungsten (W).

In some embodiments, the silicide layer 228 in combination with the metal fill 230 forms a metal silicide in the source trench and in the drain trench. Accordingly, in one or more embodiments, the source/drain trench 224 is filled with a metal silicide material comprising one or more of cobalt silicide (CoSi), molybdenum silicide (MoSi), ruthenium (RuSi), and tungsten silicide (WSi).

In some embodiments, the method 50 of FIG. 3 is integrated such that there is no vacuum break. In one or more embodiments, the growth of the source/drain material (operations 56 and 58), the replacement gate formation (operation 60), the opening of the contact trench (operation 62), and the filling of the contact trench (operation 64), can be integrated such that there is no vacuum break between the operations.

In some embodiments, the apparatus or process tool is configured to maintain the substrate under vacuum conditions to prevent formation of an oxide layer after, e.g., the deposition of the sacrificial material 116. In embodiments of this sort, the process tool is configured to move the substrate without exposing the substrate to atmospheric conditions.

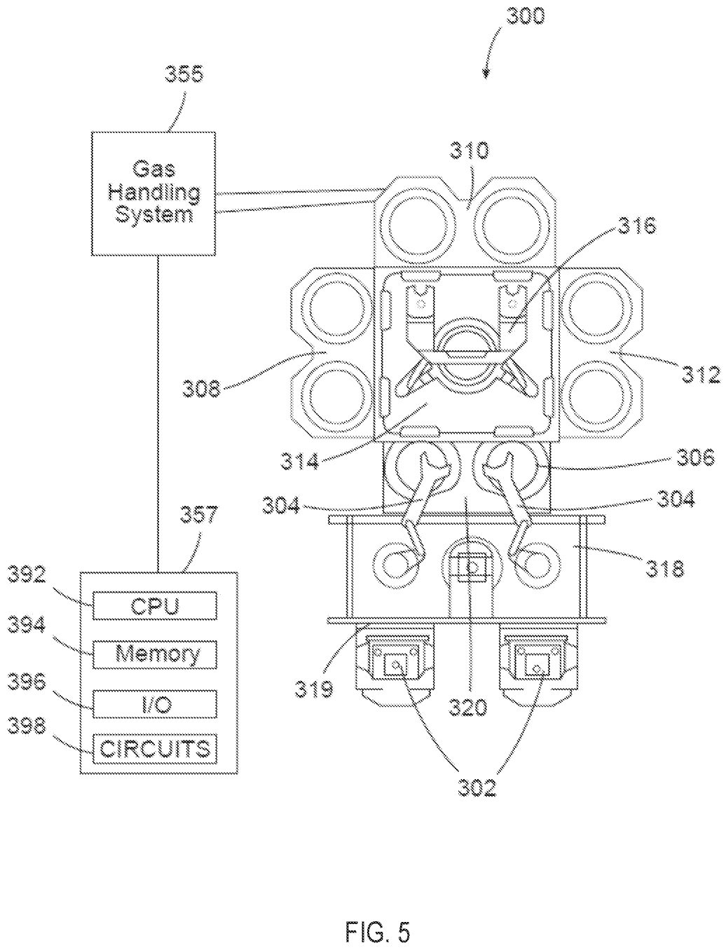

Additional embodiments of the disclosure are directed to processing tools 300 for the formation of the GAA devices and methods described, as shown in FIG. 5. A variety of multi-processing platforms, including the Centura®, Dual ACP, Producer® GT, and Endura® platform, available from Applied Materials® as well as other processing systems may be utilized. The cluster tool 300 includes at least one central transfer station 314 with a plurality of sides. A robot 316 is positioned within the central transfer station 314 and is configured to move a robot blade and a wafer to each of the plurality of sides.

The cluster tool 300 comprises a plurality of processing chambers 308, 310, and 312, also referred to as process stations, connected to the central transfer station. The various processing chambers provide separate processing regions isolated from adjacent process stations. The processing chamber can be any suitable chamber including, but not limited to, a pre-clean chamber, a deposition chamber, an annealing chamber (i.e., a template crystallizing chamber), an etching chamber, and the like. The particular arrangement of process chambers and components can be varied depending on the cluster tool and should not be taken as limiting the scope of the disclosure.

In the embodiment shown in FIG. 5, a factory interface 318 is connected to a front of the cluster tool 300. The factory interface 318 includes chambers 302 for loading and unloading on a front 319 of the factory interface 318.

The size and shape of the loading chamber and unloading chamber 302 can vary depending on, for example, the substrates being processed in the cluster tool 300. In the embodiment shown, the loading chamber and unloading chamber 302 are sized to hold a wafer cassette with a plurality of wafers positioned within the cassette.

Robots 304 are within the factory interface 318 and can move between the loading and unloading chambers 302. The robots 304 are capable of transferring a wafer from a cassette in the loading chamber 302 through the factory interface 318 to load lock chamber 320. The robots 304 are also capable of transferring a wafer from the load lock chamber 320 through the factory interface 318 to a cassette in the unloading chamber 302.

The robot 316 of some embodiments is a multi-arm robot capable of independently moving more than one wafer at a time. The robot 316 is configured to move wafers between the chambers around the transfer chamber 314. Individual wafers are carried upon a wafer transport blade that is located at a distal end of the first robotic mechanism.

A system controller 357 is in communication with the robot 316, and a plurality of processing chambers 308, 310 and 312. The system controller 357 can be any suitable component that can control the processing chambers and robots. For example, the system controller 357 can be a computer including a central processing unit (CPU) 392, memory 394, inputs/outputs 396, suitable circuits 398, and storage.

Processes may generally be stored in the memory of the system controller 357 as a software routine that, when executed by the processor, causes the process chamber to perform processes of the present disclosure. The software routine may also be stored and/or executed by a second processor (not shown) that is remotely located from the hardware being controlled by the processor. Some or all of the methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

In some embodiments, the system controller 357 has a configuration to control the deposition of the sacrificial material and to control the selective removal of the sacrificial material.

In one or more embodiments, a processing tool comprises: a central transfer station comprising a robot configured to move a wafer; a plurality of process stations, each process station connected to the central transfer station and providing a processing region separated from processing regions of adjacent process stations, the plurality of process stations comprising a template deposition chamber and a template crystallization chamber; and a controller connected to the central transfer station and the plurality of process stations, the controller configured to activate the robot to move the wafer between process stations, and to control a process occurring in each of the process stations.

One or more embodiments provide a non-transitory computer readable medium including instructions, that, when executed by a controller of a processing chamber, causes the processing chamber to perform the operations of: form a source region and a drain region adjacent a superlattice structure on a substrate, the superlattice structure comprising a plurality of horizontal channel layers and a corresponding plurality of semiconductor material layers alternatingly arranged in a plurality of stacked pairs, wherein the source region and the drain region comprise a metallic silicide material. In some embodiments, the non-transitory computer readable medium may cause the processing chamber to perform the further operations of: form a source trench and a drain trench adjacent to the superlattice structure on the substrate; deposit a sacrificial material in the source trench and in the drain trench; form a replacement metal gate structure on a top surface of the superlattice structure; open a contact trench adjacent the replacement metal gate structure, the contact trench extending to a top surface of the sacrificial material; selectively remove the sacrificial material through the contact trench; and fill the contact trench, the source trench, and the drain trench with a metal fill layer.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods, and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of forming a semiconductor device, the method comprising:
forming a source trench and a drain trench adjacent to a superlattice structure on a substrate, the superlattice structure comprising a plurality of horizontal channel layers and a corresponding plurality of semiconductor material layers alternatingly arranged in a plurality of stacked pairs;
depositing a sacrificial material in the source trench and in the drain trench;
forming a replacement metal gate structure on a top surface of the superlattice structure;
opening a contact trench adjacent the replacement metal gate structure, the contact trench extending to a top surface of the sacrificial material;
selectively removing the sacrificial material through the contact trench;
forming a source region and a drain region adjacent the replacement metal gate structure; and
filling the contact trench, the source trench, and the drain trench with a metal fill layer.

2. The method of claim 1, wherein the sacrificial material comprises one or more of silicon (Si), germanium (Ge), silicon germanium (SiGe), silicon carbide (SiC), aluminum oxide (AlOx), silicon oxide (SiOx), silicon oxycarbide (SiOC).

3. The method of claim 2, wherein the sacrificial material has a thickness in a range of from 2 nm to 50 nm.

4. The method of claim 1, wherein forming the source region and the drain region comprises growing an epitaxial layer on the plurality of semiconductor material layers in the source trench and in the drain trench and forming a conformal layer of silicide on the epitaxial layer.

5. The method of claim 1, wherein the metal fill layer comprises one or more of cobalt (Co), molybdenum (Mo), ruthenium (Ru), and tungsten (W).

6. The method of claim 4, wherein the epitaxial layer comprises one of more of silicon germanium (SiGe), silicon germanium doped with boron (SiGeB), silicon phosphorus (SiP), silicon phosphorus doped with carbon (SiPC), germanium (Ge), and germanium doped with boron (GeB).

7. The method of claim 1, wherein the plurality of semiconductor material layers and the plurality of horizontal channel layers independently comprise one or more of silicon germanium (SiGe) and silicon (Si).

8. The method of claim 1, wherein the replacement metal gate structure comprises one or more of titanium nitride (TiN), tantalum nitride (TaN), tungsten (W), and titanium aluminum (TiAl).

9. A method of forming a semiconductor device, the method comprising:
forming a source region and a drain region adjacent a superlattice structure on a substrate, the superlattice structure comprising a plurality of horizontal channel layers and a corresponding plurality of semiconductor material layers alternatingly arranged in a plurality of stacked pairs, wherein the source region and the drain region comprise a metallic silicide material.

10. The method of claim 9, wherein forming the source region and the drain region comprises:
forming a source trench and a drain trench adjacent to the superlattice structure on the substrate;
depositing a sacrificial material in the source trench and in the drain trench;
forming a replacement metal gate structure on a top surface of the superlattice structure;
opening a contact trench adjacent the replacement metal gate structure, the contact trench extending to a top surface of the sacrificial material;
selectively removing the sacrificial material through the contact trench; and
filling the contact trench, the source trench, and the drain trench with a metal fill layer.

11. The method of claim 10, wherein the sacrificial material comprises one or more of silicon (Si), germanium (Ge), silicon germanium (SiGe), silicon carbide (SiC), aluminum oxide (AlOx), silicon oxide (SiOx), silicon oxycarbide (SiOC).

12. The method of claim 10, wherein the sacrificial material has a thickness in a range of from 2 nm to 50 nm.

13. The method of claim 10, wherein the metal fill layer comprises one or more of cobalt (Co), molybdenum (Mo), ruthenium (Ru), and tungsten (W).

14. The method of claim 10, wherein forming the source region and the drain region further comprises:
growing an epitaxial layer on the plurality of semiconductor material layers in the source trench and in the drain trench prior to depositing the sacrificial material; and
forming a conformal layer of silicide on the epitaxial layer.

15. The method of claim 14, wherein the epitaxial layer comprises one of more of silicon germanium (SiGe), silicon germanium doped with boron (SiGeB), silicon phosphorus (SiP), silicon phosphorus doped with carbon (SiPC), germanium (Ge), and germanium doped with boron (GeB).

16. The method of claim 14, wherein the metal fill layer comprises one or more of cobalt (Co), molybdenum (Mo), ruthenium (Ru), and tungsten (W).

17. The method of claim 14, wherein the epitaxial layer comprises one of more of silicon germanium (SiGe), silicon germanium doped with boron (SiGeB), silicon phosphorus (SiP), silicon phosphorus doped with carbon (SiPC), germanium (Ge), and germanium doped with boron (GeB).

18. A non-transitory computer readable medium including instructions, that, when executed by a controller of a processing chamber, causes the processing chamber to perform the operations of:
form a source region and a drain region adjacent a superlattice structure on a substrate, the superlattice structure comprising a plurality of horizontal channel layers and a corresponding plurality of semiconductor material layers alternatingly arranged in a plurality of stacked pairs, wherein the source region and the drain region comprise a metallic silicide material.

19. The non-transitory computer readable medium of claim 18, that causes the processing chamber to perform the further operations of:
form a source trench and a drain trench adjacent to the superlattice structure on the substrate;
deposit a sacrificial material in the source trench and in the drain trench;
form a replacement metal gate structure on a top surface of the superlattice structure;
open a contact trench adjacent the replacement metal gate structure, the contact trench extending to a top surface of the sacrificial material;
selectively remove the sacrificial material through the contact trench; and
fill the contact trench, the source trench, and the drain trench with a metal fill layer.

20. The non-transitory computer readable medium of claim 19, that causes the processing chamber to perform the further operations of:
grow an epitaxial layer on the plurality of semiconductor material layers in the source trench and in the drain trench; and
form a conformal layer of silicide layer on the epitaxial layer.
